(19) United States
(12) Patent Application Publication
(10) Pub. No.: US 2014/0225115 A1
(43) Pub. Date: Aug. 14, 2014

(54) TENSILE POLYCRYSTALLINE SILICON FILM HAVING STABLE RESISTIVITY AND METHOD OF FABRICATING THEREOF

(71) Applicant: MACRONIX INTERNATIONAL CO., LTD., Hsin-chu (TW)

(72) Inventors: Kuang-Hui Tai, Miaoli County (TW); Hung-Yu Lin, Chiayi County (TW); Meng Shien Hsieh, Hsinchu City (TW); Teng-Chen Chiu, Hsinchu County (TW); Keng Hui Su, Hsinchu City (TW)

(73) Assignee: MACRONIX INTERNATIONAL CO., LTD., Hsin-chu (TW)

(21) Appl. No.: 13/764,349

(22) Filed: Feb. 11, 2013

(51) Int. Cl. H01L 29/04

(52) U.S. Cl. CPC H01L 29/04
USPC 257/49; 438/488

(57) ABSTRACT

Tensile polycrystalline silicon films having improved resistivity and less variability or more stable resistivity in finished semiconductors are provided. The methods of manufacturing such polycrystalline silicon films include application of protective film or film layer prior to annealing the semiconductor. Such devices and methods lead to improved stress control and resistivity.

### TECHNOLOGICAL FIELD

The present invention generally relates to a polycrystalline silicon film and a method of fabricating a polycrystalline silicon film. In particular, the present invention relates to a tensile polycrystalline silicon film having stable resistivity and a method of fabricating a tensile polycrystalline silicon film having stable resistivity.

### BACKGROUND

Stress in thin films applied to a substrate may be caused by thermal stress and/or intrinsic stress. For example, the differences in thermal expansion between the thin film and the substrate may cause a thermal stress to develop. Stress resulting from the microstructure of the deposited film itself is known as intrinsic stress. FIG. 1A illustrates a tensile stress imposed by a film 20 that has been applied to a substrate 10. On the other hand, FIG. 1B illustrates a compressive stress of the film 20 that has been applied to the substrate 10.

Amorphous silicon is compressive, but, once annealed causing the silicon to become crystallized, may become tensile in nature. Depending upon the manufacturing process, polycrystalline silicon thin films used in fabricating semiconductors may develop unstable residual stress—either tensile or compressive depending upon the severity of the annealing process. When such semiconductors are used in certain applications they may cause unstable responses.

These compressive and/or tensile effects may be more pronounced and even unacceptable when these semiconductor devices are used in micromechanical sensors. For example, (“MEMS”) microphones and pressure sensors are examples where a polysilicon diaphragm is used as a micromechanical sensor where a high degree of stability is desired. The polysilicon diaphragm may become bent upon being subjected to a low tensor stress or a compressive stress, for example. A proper degree of tensile stress in these devices will lead improved and more reliable performance in these types of semiconductor devices.

There remains a need in the art to achieve a desired tensile stress in a polysilicon film applied to a substrate and/or other layers within a semiconductor device. There remains a need in the art to provide semiconductors in certain applications having improved stability.

Conductive, in-situ doped polycrystalline silicon films are typically deposited when the film is in the amorphous state and become tensile after the semiconductor device is annealed causing the film to crystallize to a tensile state. However, during the annealing process, these films may experience an outgassing effect of the dopant leading to unstable resistivity leading to an unstable response when the semiconductor is used, for example, in a micromechanical sensor device or application.

There remains a need in the art for improved semiconductor fabrication techniques of tensile polycrystalline silicon films having improved stable resistivity.

### BRIEF SUMMARY OF EXEMPLARY EMBODIMENTS

Embodiments of the present invention are therefore provided that may provide for a polycrystalline silicon film having stable resistivity and stress.

An aspect of the invention provides a method of fabricating a semiconductor including the steps of forming a dielectric layer on a substrate, depositing a polysilicon layer on the dielectric layer, applying a film to the semiconductor, and annealing the semiconductor. The method of fabricating a semiconductor may additionally comprise the step of removing the film from the semiconductor.

In certain embodiments of the invention, a residual film may continue to be disposed along at least a periphery of a semiconductor die following the step of removing the film from the semiconductor. For example, the residual film may be a residual film layer substantially disposed along the periphery. The residual film may comprise either or both of a silicon nitride and/or a silicon oxynitride, pursuant to certain embodiments of the invention.

In an embodiment of the invention, the dielectric layer comprises at least one of a silicon oxide and a silicon oxynitride. In certain embodiments of the invention, the polysilicon layer is deposited at a deposition temperature that is from about 580° C. to about 595° C., alternatively, from about 580° C. to about 585° C.

In certain embodiments of the invention, the film is substantially disposed across the polysilicon layer, while, in other embodiments of the invention the film substantially encapsulates the semiconductor. In an embodiment of the invention, the film comprises any one of a silicon oxide, a silicon nitride, a silicon oxynitride, and any combination thereof.

In an embodiment of the invention, the step of annealing the semiconductor comprises the steps of increasing a temperature of the semiconductor to a first temperature and holding the semiconductor at the first temperature for a first amount of time. In certain embodiments of the invention, the step of annealing the semiconductor additionally comprises the steps of increasing the temperature of the semiconductor to a second temperature and holding the semiconductor at the second temperature for a second amount of time. In certain embodiments of the invention, the first temperature is from about 800° C. to about 950° C. and the second temperature is from about 1000° C. to about 1100° C. In certain embodiments of the invention the first amount of time may be greater than the second amount of time.

In an embodiment of the invention, the film comprises a silicon nitride and the film is removed using a wet process comprising a hot phosphoric acid. In other embodiments of the invention, the film may comprise a silicon oxynitride and the film is removed using a wet process comprising a hydrofluoric acid based solution.

An aspect of the invention provides a semiconductor comprising a substrate, a dielectric layer and a polysilicon layer having a stress of from about 10 MPa to about 40 MPa. In an embodiment of the invention, the dielectric layer comprises a silicon oxide and has a stress of from about −330 MPa to about −270 MPa. In other embodiments of the invention the dielectric layer comprises at least one of a silicon oxide layer having a stress of about −145 MPa to about −105 Mpa and a silicon oxynitride layer having a stress of about 10 MPa to about 30 MPa.

In certain embodiments of the invention, the semiconductor may additionally comprise a film, wherein the film is at least one of applied to a surface of the polysilicon layer and/or substantially encapsulates the semiconductor. In certain embodiments of the invention, the semiconductor comprises any one of a silicon oxide, a silicon nitride, or a silicon oxynitride.

An aspect of the invention provides a semiconductor comprising a substrate; a dielectric layer; and a polysilicon layer deposited at a temperature from about 580° C. to about 595° C., wherein the semiconductor has been annealed at a first temperature and at a second temperature with a film applied to the semiconductor. According to an embodiment of the invention, the semiconductor may additionally comprise a residual film layer disposed, at least in part, along a sidewall of the semiconductor. Such residual film layer may remain following the removal of the film. In an embodiment of the invention, the residual film layer may comprise one or both of silicon nitride and a silicon oxynitride.

These embodiments of the invention and other aspects and embodiments of the invention will become apparent upon review of the following description taken in conjunction with the accompanying drawings. The invention, though, is pointed out with particularity by the appended claims.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1A illustrates a tensile stress imposed by a film disposed upon a substrate;

FIG. 1B illustrates a compressive stress imposed by a film disposed upon a substrate;

FIG. 2 illustrates a cross section of a semiconductor having a dielectric layer formed on a substrate and a polysilicon layer disposed there upon according to an embodiment of the invention;

FIG. 3 illustrates a particle doping of a semiconductor according to an embodiment of the invention;

FIG. 4 illustrates a cross section of a semiconductor that has been encapsulated by a film according to an embodiment of the invention;

FIG. 5 illustrates a cross section of a semiconductor that has been capsulized after being annealed according to an embodiment of the invention;

FIG. 6A illustrates a sketch of a discrete semiconductor die according to an embodiment of the invention;

FIG. 6B illustrates a cross section of a semiconductor die after removal of the encapsulated film on the main active area according to another embodiment of the invention;

FIG. 6C illustrates a cross section of a semiconductor after removal of the encapsulated film according to another embodiment of the invention;

FIG. 7 illustrates a cross section of a semiconductor having a film layer formed upon the polysilicon layer according to another embodiment of the invention;

FIG. 8 illustrates a cross section of a semiconductor that has a film layer formed upon the polysilicon layer after being annealed according to another embodiment of the invention;

FIG. 9A illustrates a cross section of a discrete semiconductor die after removal of the film layer according to another embodiment of the invention;

FIG. 9B illustrates a cross section of a discrete semiconductor die after removal of the film layer according to another embodiment of the invention;

FIG. 10 shows the path that ions may take through a polysilicon layer;

FIG. 11 is a graphical representation of the concentration of ions at various depths throughout a polysilicon layer;

FIG. 12 illustrates a beam of charged atoms or molecules directed to a substrate during ion implantation;

FIG. 13A is a theoretical graphical representation of dopant profiles in a polysilicon layer that has undergone a high temperature annealing;

FIG. 13B is a theoretical graphical representation of dopant profiles in a polysilicon layer that has undergone annealing at a more conventional temperature;

FIG. 13C is a theoretical graphical representation of dopant profiles in a polysilicon layer that has undergone a low temperature annealing;

FIG. 14 is a graphical representation of the grain boundary diffusion of phosphorous in polycrystalline silicon;

FIG. 15 is a graphical representation of polycrystalline silicone resistivity versus implantation energy and dosage;

FIG. 16 is a graphical representation of polysilicon resistivity of a semiconductor that has been encapsulated with a film prior to being subjected to annealing according to an embodiment of the invention;

FIG. 17 is a graphical representation of polysilicon resistivity of a semiconductor that has not been encapsulated with a film prior to being subjected to annealing;

FIG. 18 is a flowchart of a process for fabricating a semiconductor according to an embodiment of the invention;

FIG. 19 is a flowchart of a process for fabricating a semiconductor according to another embodiment of the invention; and

FIG. 20 is a flowchart of a process for fabricating a semiconductor according to yet another embodiment of the invention.

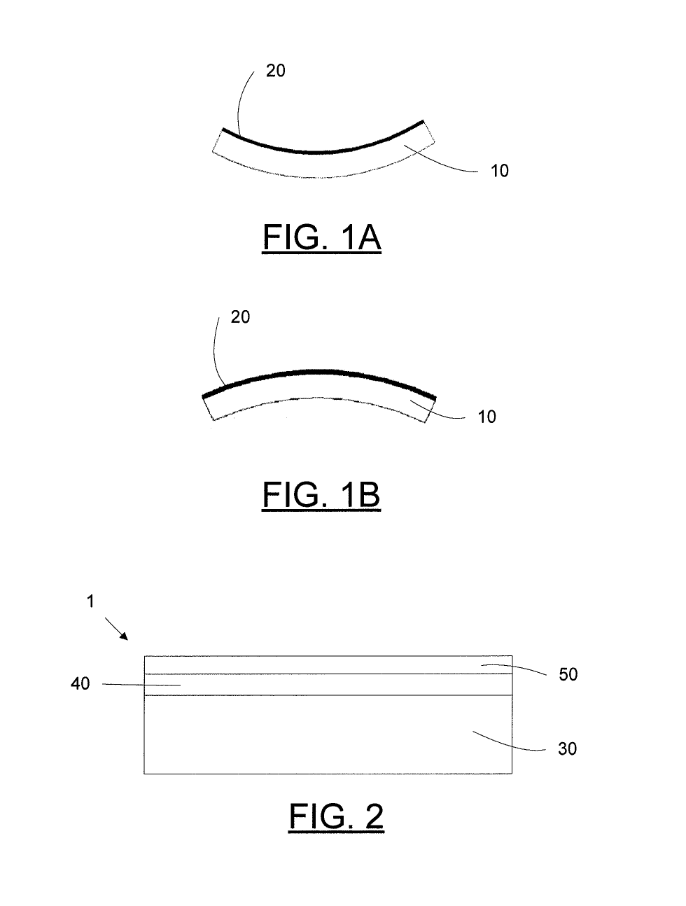

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a polysilicon film” includes a plurality of such polysilicon films.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “compressive stress” is intended to mean the stress imparted on a semiconductor when equal forces are applied in an inward direction relative to the semiconductor. The length of the semiconductor tends to decrease in the direction of the compressive force.

As used herein, “tensile stress” is intended to mean the stress imparted on a semiconductor when equal and opposite forces are applied in an outward direction relative to the semiconductor. The length of the semiconductor tends to increase in the direction of the tensile force.

The inventors have conceived of and have developed systems, processes and methodologies for improved fabrication of semiconductor devices. In particular, the inventors have conceived of and developed systems, processes and methodologies for achieving a desired tensile stress in a semiconductor wafer and reducing the resistivity of the semiconductor. In certain embodiments of the invention, the variability in resistivity of the semiconductor is also reduced.

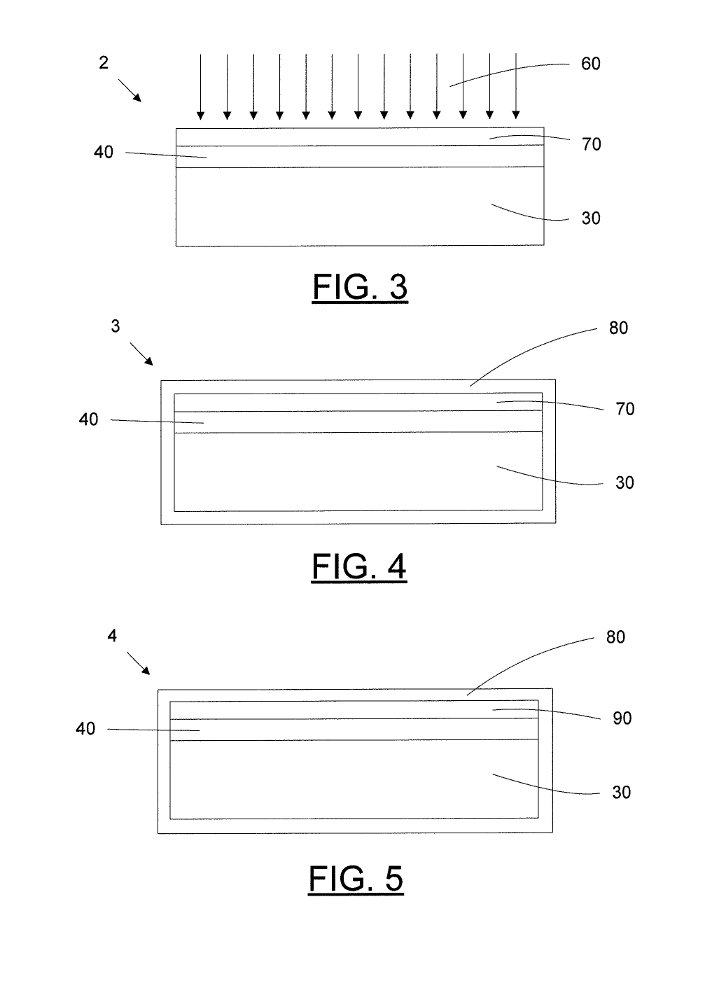

FIG. 2 illustrates a cross section of a semiconductor according to an embodiment of the invention. This illustrative embodiment shows a semiconductor 1 having a substrate 30 following the formation of a dielectric layer 40 and application of a polysilicon layer 50. FIG. 3 illustrates a cross section of a semiconductor 2, according to an embodiment of the invention, as the polysilicon layer 50 is being deposited with a dopant source 60 to form a doped polysilicon layer 70. The cross section of the semiconductor 3 of the illustrative embodiment represented by FIG. 4 shows that the semiconductor 2 represented by FIG. 3 has been substantially encapsulated by a film 80.

The dielectric layer 40 may comprise, for example, a silicon oxide layer or a silicon nitride layer. In certain embodiments of the invention, the dielectric layer 40 may comprise a silicon oxynitride (SiOxNy) layer. In certain embodiments of the invention, the dielectric layer 40 may comprise a silicon oxide layer and a silicon oxynitride layer. The dielectric layer 40 may be formed using any know silicon oxide layer formation technique known in the art. The dielectric layer 40 may be deposited using a chemical vapor deposition technique. In certain embodiments of the invention, the dielectric layer 40 may be formed as a wet oxide layer is grown using, for example, an atmospheric pressure chemical vapor deposition (“APCVD”). In certain embodiments of the invention, the dielectric layer 40 may be formed as a wet oxide layer is grown using, for example, a low pressure chemical vapor deposition (“LPCVD”).

In an embodiment of the invention, the dielectric layer 40 may be from about 2,000 Å to about 10,000 Å, from about 3,000 Å to about 9,000 Å, from about 4,000 Å to about 8,000 Å, from about 5,000 Å to about 7,000 Å, and from about 5,400 Å to about 6,600 Å in thickness. In an embodiment of the invention, the dielectric layer 40 may be about 6,000 Å in thickness.

The properties of the dielectric layer 40, may be adjusted using, for example, process parameters of the deposition technique or of the material applied to the surface of the substrate 30 to provide a desired stress of the dielectric layer 40. The stress of the dielectric layer 40 may be from about −400 MPa to about −50 MPa, from about −350 MPa to about −100 MPa, and from about −330 MPa to about −115 MPa. In certain embodiments of the invention, the dielectric layer 40 may be a silicon oxide layer having a stress of from about −330 MPa to about −270 MPa. In certain embodiments of the invention, the stress of the silicon oxide layer may be about −300 MPa. In certain other embodiments of the invention, the dielectric layer 40 may be a silicon oxide layer having a stress of from about −145 MPa to about −115 MPa. In certain other embodiments of the invention, the stress of the oxide layer may be about −130 MPa.

Pursuant to those embodiments of the invention where the dielectric layer 40 comprises a silicon oxide layer and a silicon oxynitride layer, the stress of the silicon oxynitride layer may be used to adjust the stress of the finished semiconductor once fabrication of the semiconductor is complete. In certain embodiments of the invention, the stress of the silicon oxynitride layer may be from about 0 MPa to about 100 MPa, 5 MPa to about 50 MPa, and from about 10 MPa to about 30 MPa. In certain embodiments of the invention, the stress of the silicon oxynitride layer may be about 20 MPa. In an embodiment of the invention, the silicon oxynitride layer is applied using a plasma-enhanced chemical vapor deposition (“PECVD”) to achieve the desired stress of the layer.

In an embodiment of the invention, the polysilicon layer 50 may be from about 2,000 Å to about 8,000 Å, from about 3,000 Å to about 9,000 Å, from about 4,000 Å to about 8,000 Å, from about 5,000 Å to about 7,000 Å, and from about 5,400 Å to about 6,600 Å in thickness. In an embodiment of the invention, the dielectric layer 40 may be about 6,000 Å in thickness.

The polysilicon layer 50 applied to the dielectric layer 40 may be compressive or tensile. In certain embodiments of the invention, the polysilicon layer 50 is only slightly tensile. The stress of the polysilicon layer 50, according to certain embodiments of the invention, may be from about 0 MPa to about 100 MPa, from about 2 MPa to about 50 MPa, from about 5 MPa to about 40 MPa, and from about 10 MPa to about 40 MPa. In an embodiment of the invention, the stress of the polysilicon layer 50 may be from about 20 MPa to about 40 MPa. In certain embodiments of the invention, the stress of the polysilicon layer 50 may be about 30 MPa. In another embodiment of the invention, the stress of the polysilicon layer 50 may be from about 10 MPa to about 30 MPa. In certain other embodiments of the invention, the stress of the polysilicon layer 50 may be about 20 MPa.

Ion implantation, as illustrated, for example, in FIG. 3, is a process where charge atoms are directly introduced into a substrate, for example, in the polysilicon layer 50 to add dopant ions into the surface of the polysilicon layer 50 resulting in the doped polysilicon layer 70. Charge atoms that are directly introduced in the substrate are introduced into the substrate in the absence of any substantial tilt angle, as further described herein. An ion implanter delivers a beam of a certain type of ions having a certain energy to the surface of the polysilicon layer 50. Acceleration energies of the ions may be in a range of from about 10 keV to about 200 keV. As the ions enter the layer, they eventually are stopped and become implanted in the layer. For example, an ion may be stopped as a result of one or more collisions with other atoms in the polysilicon layer or as a result of interactions with electrons in the polysilicon layer.

As the ions collide with atoms in the polysilicon layer, the atoms within the polysilicon layer themselves may become displaced resulting in a more highly disordered state. Subsequent processing techniques may be used to correct, to some extent, the disorder caused by these collisions. Thus, ion implantation typically is used when the polysilicon layer is in an amorphous state, and subsequent processing, as further described herein, causes the layer to transform into a more highly ordered crystalline form.

When it is desired to achieve a relatively deep penetration of ions, then these ions must have greater energies needed to penetrate the layer and travel deeper within the layer. These higher energies may cause the polysilicon layer to become more disordered as a result of higher energy collisions between the ions and the atoms of the layer.

Channeling occurs when ions traveling through the polysilicon layer are directed through open-spaces that define or are within the layer. Ions are directed to these channels by collisions with atoms in the layer. Once these ions become directed to a channel, then they may continue to proceed traveling through the channel substantially free of collisions with atoms and undisturbed thus resulting in an ion distribution that is deeper within the layer.

FIG. 10 shows the path that ions may take through an exemplary portion of a polysilicon layer 100. Path A 110 shows the path of an ion in a channel that is substantially free of any collisions with atoms in the network. Ions traveling according to a path similar to path A 110 may only become stopped in the layer as a result of interactions with electrons in the layer. Thus ions traveling along a path similar to path A 110 can be expected to penetrate deeply into the layer. Path B 120 shows the path of an ion that collides with an ion in the layer 100 and becomes redirected to another channel within the layer 100. Path C 130 is representative of an ion not experiencing a high degree of channeling in the layer 100.

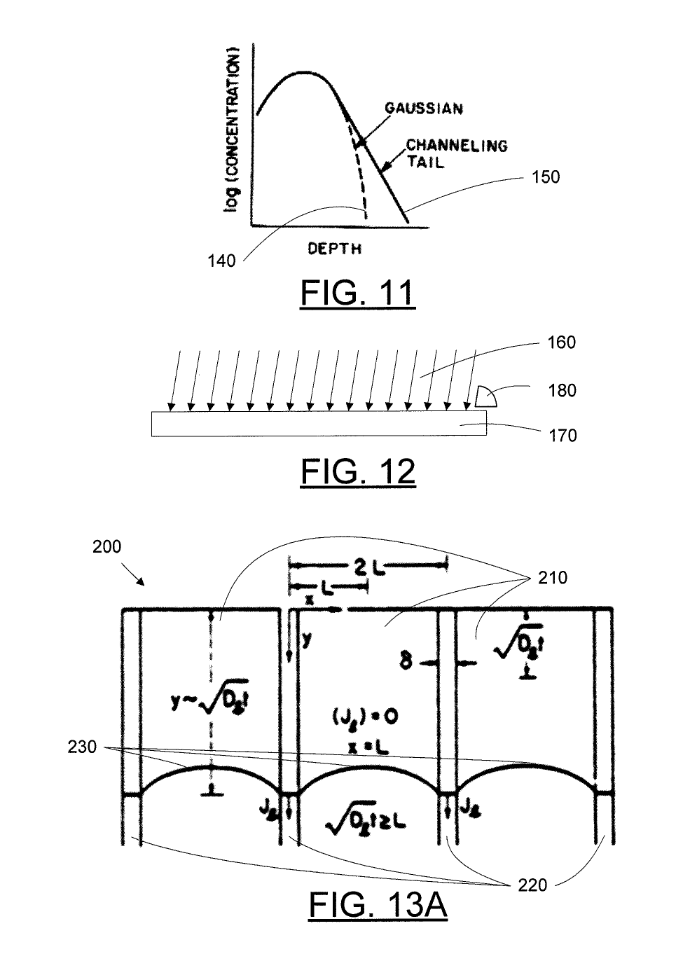

Conventionally, channeling is not preferred. While channeling does allow some ions to penetrate deeper into the layer and to avoid less damage to the layer as a result of reduced collisions with atoms in the layer, such penetration is achieved more by chance and may result in a more non-random distribution of ions throughout the layer. Indeed, channeling results in adding a tail to the implanted distribution. FIG. 11 is a graphical representation of the concentration of ions at various depths throughout the layer. The Gaussian curve 140 is representative of a more random and orderly progression of ions throughout the layer that did not undergo a high degree of channeling while the channeling tail 150 is variable and results from ions that have experienced channeling within the layer.

While channeling may be substantially reduced or even eliminated to some degree in an amorphous layer of silicon, in practice channeling has also been reduced, if not eliminated entirely, by titling the semiconductor wafer relative to the direction of the ion beam. FIG. 12 is representative of a beam 160 of charged atoms or molecules being directed to a substrate 170, such as a polysilicon layer. The tilt angle 180 is defined as the angle of the beam 160 relative to the surface of the substrate 170.

According to an embodiment of the invention, doping of the polysilicon layer through ion implantation is such that the extent of channeling in the polysilicon layer is maximized. In certain embodiments of the invention, the tilt angle 180 of the beam 160 relative to the polysilicon layer is from about 0 degrees to about 7 degrees, from about 0 degrees to about 5 degrees, from about 0 degrees to about 3 degrees, and from about 0 degrees to about 1 degree. In an embodiment of the invention, the tilt angle 180 of the beam 160 relative to the polysilicon layer is about 0 degrees.

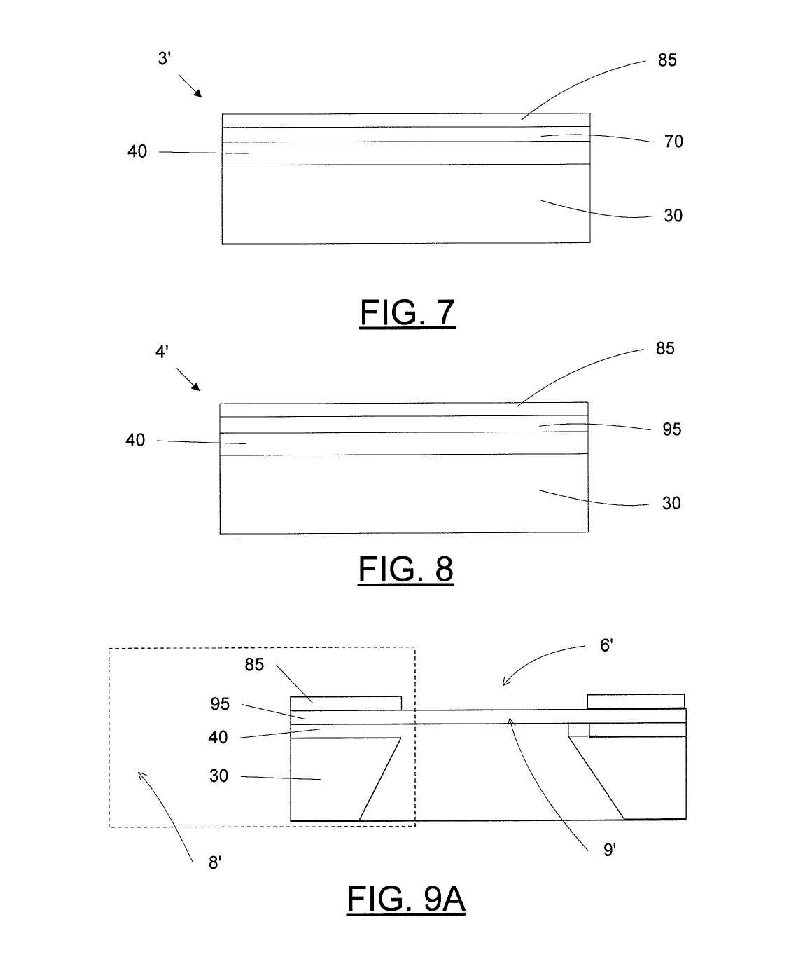

In another embodiment of the invention, instead of encapsulating the structure, a film layer 85 is substantially disposed along the doped polysilicon layer 70 as illustrated in FIG. 7.

The film 80 or the film layer 85 may comprise a silicon nitride layer, a silicon oxide layer, or a silicon oxynitride layer. In certain embodiments of the invention, the film 80 or the film layer 85 may comprise either a silicon nitride layer or a silicon oxynitride layer.

In an embodiment of the invention, the film 80 encapsulating the structure or the film layer 85 may be from about 100 Å to about 5,000 Å, from about 500 Å to about 4,000 Å, from about 1,000 Å to about 3,000 Å, from about 1,500 Å to about 2,500 Å, and from about 1,800 Å to about 2,200 Å in thickness. In an embodiment of the invention, the film 80 or the film layer 85 may be about 2,000 Å in thickness.

The stress of the film 80 or the thin layer 85, according to certain embodiments of the invention, may be from about 0 MPa to about 500 MPa, from about 20 MPa to about 400 MPa, from about 50 MPa to about 300 MPa, and from about 90 MPa to about 255 MPa. In an embodiment of the invention, the stress of the film 80 or the film layer 85 may be from about 90 MPa to about 110 MPa. In certain embodiments of the invention, the stress of the film 80 or the film layer 85 may be about 100 MPa. According to another embodiment of the invention, the stress of the film 80 or the film layer 85 may be from about 205 MPa to about 255 MPa. In certain embodiments of the invention, the stress of the film 80 or the film layer 85 may be about 230 MPa.

Table 1 provides a summary of some combinations of the semiconductor 3 of FIG. 4 having a dielectric layer 40, a polysilicon layer 50 that is deposited to produce a doped polysilicon layer 70, and a film 80 that encapsulates the structure, and the semiconductor 3′ of FIG. 7 having a dielectric layer 40, a polysilicon layer 50 that is deposited to produce a doped polysilicon layer 70, and having a film layer 85 deposited substantially along the doped polysilicon layer 70 according to various embodiments of the invention.

TABLE 1

| | Dielectric Layer | | | | | | Polysilicon Layer | | | | Film or Film Layer | | | | |
|---|---|---|---|---|---|---|---|---|---|---|---|---|---|---|---|
| Example | Type | Process | Thickness | | Stress | | Thickness | | Stress | | Type | Thickness | | Stress | |
| 1 | Silicon | APCVD | 6000 | +/− | −300 | +/− | 4000 | +/− | 30 | +/− | Silicon | 2000 | +/− | 230 | +/− |
| | Oxide | | 600 | Å | 30 | MPa | 400 | Å | 10 | MPa | Nitride | 200 | Å | 25 | MPa |
| 2 | Silicon | APCVD | 6000 | +/− | −300 | +/− | 4000 | +/− | 30 | +/− | Silicon | 2000 | +/− | 230 | +/− |
| | Oxide | | 600 | Å | 30 | MPa | 400 | Å | 10 | MPa | Oxynitride | 200 | Å | 25 | MPa |
| | | | | | | | | | | | (PECVD) | | | | |
| 3 | Silicon | LPCVD | 6000 | +/− | −130 | +/− | 4000 | +/− | 30 | +/− | Silicon | 2000 | +/− | 100 | +/− |
| | Oxide | | 600 | Å | 15 | MPa | 400 | Å | 10 | MPa | Nitride | 200 | Å | 10 | MPa |
| | | | | | | | | | | | (PECVD) | | | | |
| 4 | Silicon | LPCVD | 6000 | +/− | −130 | +/− | 4000 | +/− | 30 | +/− | Silicon | 2000 | +/− | 100 | +/− |
| | Oxide | | 600 | Å | 15 | MPa | 400 | Å | 10 | MPa | Oxynitride | 200 | Å | 10 | MPa |
| | | | | | | | | | | | (PECVD) | | | | |
| 5 | Silicon | APCVD | 6000 | +/− | −300 | +/− | 4000 | +/− | 20 | +/− | Silicon | 2000 | +/− | 230 | +/− |
| | Oxide | | 600 | Å | 30 | MPa | 400 | Å | 10 | MPa | Nitride | 200 | Å | 25 | MPa |
| | Silicon | PECVD | | | 20 | +/− | | | | | | | | | |
| | Oxynitride | | | | 10 | MPa | | | | | | | | | |
| 6 | Silicon | APCVD | 6000 | +/− | −300 | +/− | 4000 | +/− | 20 | +/− | Silicon | 2000 | +/− | 230 | +/− |
| | Oxide | | 600 | Å | 30 | MPa | 400 | Å | 10 | MPa | Oxynitride | 200 | Å | 25 | MPa |
| | Silicon | PECVD | | | 20 | +/− | | | | | (PECVD) | | | | |
| | Oxynitride | | | | 10 | MPa | | | | | | | | | |
| 7 | Silicon | LPCVD | 6000 | +/− | −130 | +/− | 4000 | +/− | 20 | +/− | Silicon | 2000 | +/− | 100 | +/− |
| | Oxide | | 600 | Å | 15 | MPa | 400 | Å | 10 | MPa | Nitride | 200 | Å | 10 | MPa |
| | Silicon | PECVD | | | 20 | +/− | | | | | (PECVD) | | | | |
| | Oxynitride | | | | 10 | MPa | | | | | | | | | |
| 8 | Silicon | LPCVD | 6000 | +/− | −130 | +/− | 4000 | +/− | 20 | +/− | Silicon | 2000 | +/− | 100 | +/− |
| | Oxide | | 600 | Å | 15 | MPa | 400 | Å | 10 | MPa | Oxynitride | 200 | Å | 10 | MPa |
| | Silicon | PECVD | | | 20 | +/− | | | | | (PECVD) | | | | |
| | Oxynitride | | | | 10 | MPa | | | | | | | | | |

As shown in Table 1, in an embodiment of the invention, the dielectric layer comprises a silicon oxide. In certain embodiments of the invention, the dielectric layer comprises a silicon oxynitride. In certain embodiments of the invention, the dielectric layer may comprise a silicon oxide and a silicon oxynitride. Further pursuant to these certain embodiments of the invention, the silicon oxynitride is included to achieve a desired stress of the semiconductor device once the film or film layer is removed from the semiconductor device.

In an embodiment of the invention, the stresses and thicknesses of the dielectric layer, the polysilicon layer, and the film or film layer may be adjusted to provide a semiconductor having a desired tensile stress. In other embodiments of the invention, the stresses and thicknesses of the dielectric layer, the polysilicon layer, and the film or film layer may be adjusted to provide a semiconductor having no stress or, alternatively, a compressive stress. In yet other embodiments of the invention, the RF power or gas flow of a deposition technique, techniques known by those of ordinary skill in the art having the benefit of this disclosure, may be adjusted to change, for example, the composition of the silicon oxynitride film to achieve a desired tensile stress, alternatively, no stress, or even a compressive stress of the semiconductor.

In certain embodiments of the invention, the polysilicon layer is as grown polysilicon. In certain other embodiments of the invention, the polysilicon layer is an in situ polysilicon. Table 2 shows film properties for varying deposition conditions for as-grown polysilicon layers and in situ polysilicon layers.

TABLE 2

| | Deposition | Grain Size | | | | |
|---|---|---|---|---|---|---|
| Poly | Temperature, | Average, | | | | R_{d}, |
| Material | ° C. | Å | D₂₂₀, Å | Optical | Sᵣ, Å | Å/min |
| as grown | 560 | 50 | 50 | amorphous | <15 | 23 |
| as grown | 570 | 95 | 95 | amorphous | <15 | 27 |
| as grown | 580 | 140 | 290 | <311> | <15 | 33 |
| as grown | 600 | 230 | 340 | <311> | 20 | 52 |
| as grown | 620 | 310 | 770 | <111> | 52 | 100 |
| as grown | 640 | 400 | 2000 | <111> | 60 | 180 |
| in situ | 560 | 140 | 140 | amorphous | <15 | 25 |
| in situ | 570 | 400 | 400 | amorphous | <15 | 28 |
| in situ | 580 | 670 | 610 | <311> | <15 | 32 |
| in situ | 600 | 580 | 460 | <111> | 18 | 52 |
| in situ | 620 | 420 | 470 | <311> | 20 | 75 |
| in situ | 640 | 280 | 400 | <311> | 80 | 143 |

The as grown polysilicon layers in Table 2 were deposited at a deposition pressure of about 120 mTorr and a silane gas flow rate of about 50 cm⁻³, while, the in situ polysilicon layers were deposited at a deposition pressure of about 500 mTorr and a silane gas flow rate of about 300 cm⁻³.

Sᵣ represents the surface roughness or roughness in Angstroms. Surface roughness is a measure of the uniformity, or lack of uniformity, of the texture of the surface. The roughness of the surface is quantified by vertical deviations in the actual surface over an ideal surface that substantially lacks any deviations. Relatively small deviations are more characteristic of a surface that is smooth while relatively large deviations are more characteristic of a surface that is rough. Rd is the deposition rate of the film measured in Angstroms/minute.

Additional information may be found in the following references: Harbeke, G., L. Krausbauer, E. Steigmeir, A. Widmer, H. Kappert, and G. Neugebaurer, “LPCVD Polycrystalline Silicon: Growth and Physical Properties of in-situ Phosphorous Doped and Undoped Films,” RCA Review, Vol. 44, 1983, pp. 287-312; Duffy, M., J. McGinn, J. Shaw, R. Smith, R. Soltis, and G. Harbeke, “LPCVD Polycrystalline Silicon: Growth and Physical Properties of Diffusion-Dopes, Ion-Implanted, and Undoped Films,” RCA Review, Vol. 44, 1983, pp. 313-325; and Harbeke, G., L. Krausbauer, E. Steigmeir, A. Widmer, H. Kappert, and G. Neugebaurer, “Growth and Physical Properties of LPCVD Polycrystalline Silicon Films,” J. Electrochem. Sol., Vol. 131, No. 3, 1984, pp. 675-682.

According to certain embodiments of the invention, the polysilicon layer is an as grown polysilicon layer deposited at a temperature within a range of from about 570° C. to about 600° C., from about 575° C. to about 595° C., and from about 580° C. to about 595° C. In certain embodiments of the invention, the polysilicon layer is an as grown polysilicon layer deposited at a temperature of about 580° C. In yet other embodiments of the invention, the polysilicon layer is an as grown polysilicon layer deposited at a temperature of about 585° C.

In other embodiments of the invention, the polysilicon layer may be applied by sputter deposition. In alternative embodiments, the conditions of the polysilicon layer deposition may be such that the polysilicon layer has an amorphous structure and the structure is changed using an annealing process.

According to certain embodiments of the invention, the film that encapsulates the semiconductor of the film layer deposited substantially along the doped polysilicon layer comprises a silicon nitride. In certain embodiments of the invention, the film that encapsulates the semiconductor of the film layer deposited substantially along the doped polysilicon layer comprises a silicon oxynitride.

Reaction 1 represents the formation of silicon nitride using a low pressure chemical vapor deposition (“LPCVD”).

3SiH₂Cl₂+4NH₃→Si₃N₄+6HCl+6H₂ (1)

Reactions 2-4 represent the formation of silicon nitride using a plasma enhanced chemical vapor deposition (“PECVD”).

3SiH₄(g)+4NH₃(g)→Si₃N₄(s)+12H₂(g) (2)

3SiCl₄(g)+4NH₃(g)→Si₃N₄(s)+12HCl(g) (3)

3SiCl₂H₂(g)+4NH₃(g)→Si₃N₄(s)+6HCl(g)+6H₂(g) (4)

In certain embodiments of the invention, any of the silicon oxynitride of the first layer, the silicon oxynitride of the film or film layer, and/or the silicon nitride of the film or film layer may be deposited using a plasma-enhanced chemical vapor deposition method or technique to adjust the stress of the semiconductor as well as the compositions of the applied layers.

As already stated herein, subjecting the polysilicon layer to thermal annealing may serve to correct some of the damage caused by ions colliding with the atoms in the layer. Thermal annealing is process where the semiconductor is heated to a suitable temperature. Thermal annealing helps to diffuse dopant atoms or molecules more evenly throughout the polysilicon layer as well as to activate the dopant atoms or molecules. U.S. Pat. No. 4,089,992 entitled “Method for Depositing Continuous Pinhole Free Silicon Nitride Films and Products Produced Thereby” to Doo et al. (“Doo”) report, as shown in Table 3, the junction depth and surface concentration of various dopants in silicon and germanium substrates at different diffusion conditions.

TABLE 3

| Substrate | | | Diffusion Temperature | | | Concen- |
|---|---|---|---|---|---|---|
| | Thickness, | | (° C.)/Time (min) | | Junction | tration |
| Type | Å | Dopant | Deposit | Drive-in | Depth | (atoms/cm) |
| Si | 1200 | B | 980/30 | 1200/30 | 2.07 | 7 × 10¹⁹ |
| Si | 1200 | P | 1100/10 | 1100/20 | 1.8 | 1 × 10²¹ |
| Si | 150 | As | | 1200/120 | 1.44 | 1.4 × 10²⁰ |
| Si | 250 | Ga | | 1100/90 | 3.2 | 4 × 10¹⁹ |
| Si | 250 | O | | 1150/20 | 0.5 | — |
| Ge | 250 | Ga | | 800/120 | 0.92 | 1 × 10¹⁹ |

Additionally, Shimakura, K., T. Suzuki, and Y. Yadoiwa, “Boron and Phosphorus Diffusion Through an SiO₂ Layer from a Doped Polycrystalline Source under Various Drive-In Ambients,” Solid State Electronics 18:991 (1975) reports that the dopant phosphorus has the diffusion rates and activation energies of diffusion identified in Table 4 at various annealing conditions.

TABLE 4
Inert Gas

| Layer | Diffusivity, cm²/s | Activation Energy, eV |
|---|---|---|
| Silicon Dioxide | 1.5 × 10⁻¹⁷ | 4.0 |
| Silicon Dioxide | 3 × 10⁻¹⁸ | 4.4 |
| Polysilicon | 3.5 × 10⁻¹⁶ | 4.4 |

Wong, C. and F. Lai, “Ambient and Dopant Effects on Boron Diffusions in Oxides,” Appl. Phys. Lett. 48:1658 (1986) reports boron has a diffusion rate of 7×10⁻¹⁷ in silicon dioxide and an activation energy of diffusion of 3.3 eV.

Conventionally, thermal annealing involves heating the semiconductor anywhere in the temperature range of from about 500° C. to about 1,500° C. for a certain period of time—typically on the order of a few minutes to a minute or even less. However, the process of annealing may impart sufficient energy to the dopant to also cause the outgassing of the doping particle, which may lead to further deterioration of the polysilicon layer as well as the silicon oxide layer disposed between the substrate and the polysilicon layer. Doo discloses that a silicon nitride film used as a mask for many common dopants in silicon. However, Doo does not recognize that dopant outgassing may also lead to deterioration in the compressive stress of device.

The inventors have conceived of disposing a film surrounding the semiconductor or at least a film layer disposed across the surface of the polysilicon layer as shown in FIGS. 4 and 7, respectively, to prevent the outgassing of the dopant particles and to substantially reduce the deterioration arising from damage that the movement of particles may induce upon the polysilicon layer.

Following disposing the film surrounding the semiconductor or a film layer across the surface of the polysilicon layer, the semiconductor is subjected to an annealing process. The annealing process, for example, may include a laser annealing process, an electron beam annealing process, and a thermal annealing process. In certain embodiments of the invention, a thermal annealing process heats the semiconductor to a certain temperature in the presence of an inert gas.

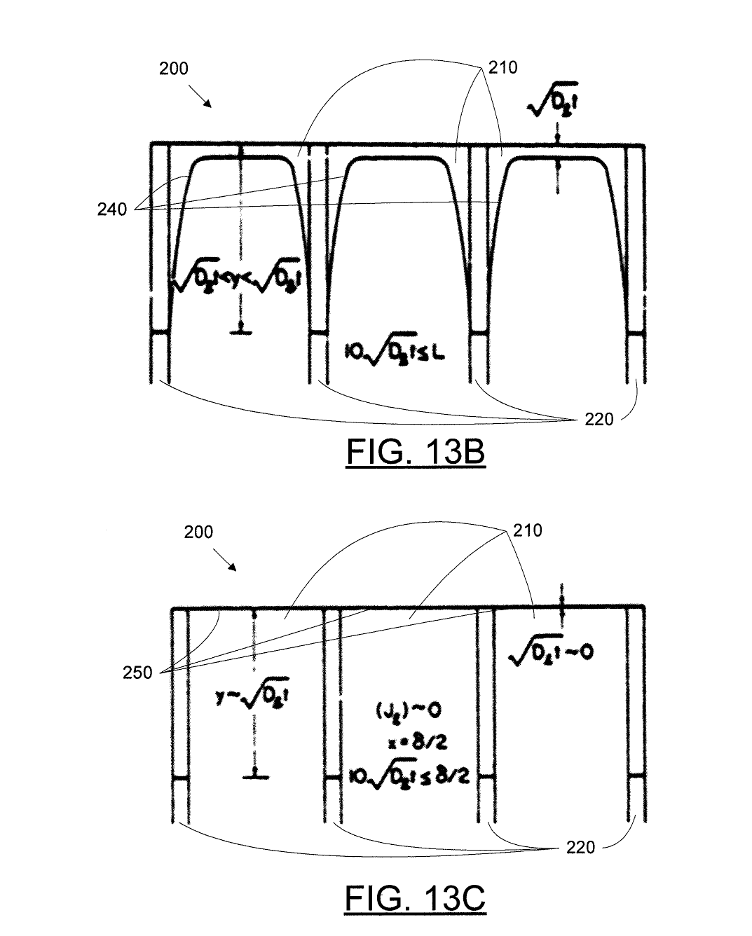

FIG. 13A is a theoretical graphical representation of dopant profiles in an exemplary section of a polysilicon layer 200 that has been subjected to a high temperature annealing—e.g., annealing at a temperature in excess of about 1150° C. The polysilicon layer 200 includes a plurality of grains 210 separated by a plurality of grain boundaries 220. As shown in FIG. 13A, diffusion of the dopant as represented by the diffusion front 230 through each of the grains 210 is somewhat subdued at high temperature annealing, and the speed of dopant diffusion across the grains 210 is just a little lower than dopant diffusions along the grain boundary 220.

FIG. 13B is a theoretical graphical representation of dopant profiles in a polysilicon layer that has undergone annealing at a more conventional temperature—e.g., annealing at a temperature of about 1050° C. As shown in FIG. 13B, diffusion of the dopant as represented by the diffusion front 240 through the grains 210 is lower than dopant diffusion along the grain boundary 220.

FIG. 13C is a theoretical graphical representation of dopant profiles in an exemplary section of a polysilicon layer 200 that has been subjected to a low temperature annealing—e.g., annealing at a temperature less than about 800° C. As shown in FIG. 13C, diffusion of the dopant as represented by the diffusion front 250 is mainly along the grain boundary 220. Thus, FIGS. 13A-13C show that dopant can diffuse more deeply and become more concentrated by low temperature annealing.

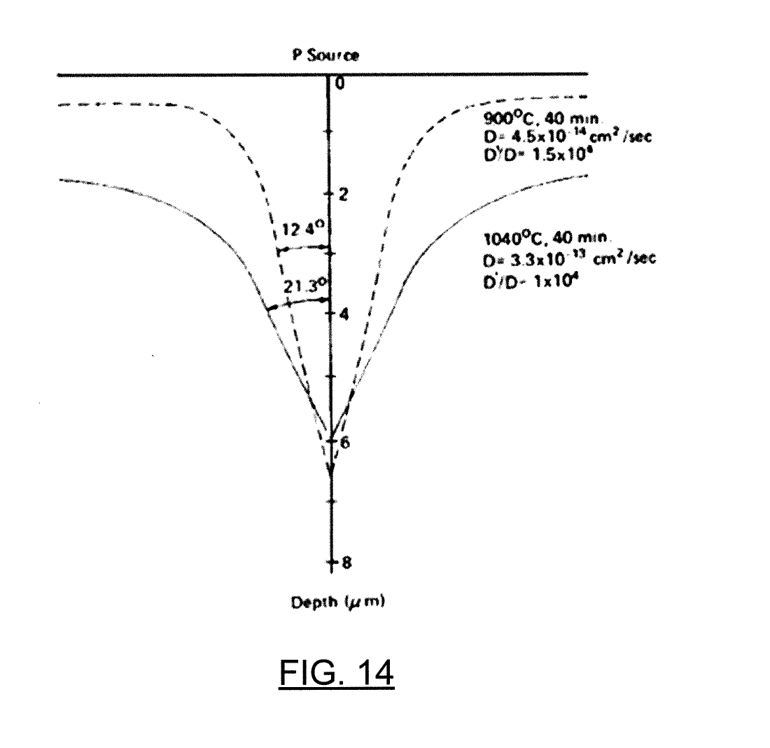

FIG. 14 is a graphical representation of the grain boundary diffusion of phosphorous in polycrystalline silicon. This figure illustrates the relation between diffusion depth and annealing temperatures. Thus, FIG. 14 shows that phosphorous can diffuse more deeply by low temperature annealing.

In certain embodiments of the invention, the semiconductor is subjected to a two-step temperature annealing process wherein the semiconductor is subjected to a first temperature followed by subjecting the semiconductor to a second temperature. Without intending to be bound by theory, the conditions of one of the steps are such that diffusion of the dopant through the grain is promoted, and the condition of the other of the steps are such that diffusion of the dopant across the grain are promoted. In certain embodiments of the invention, the first temperature is lower than the second temperature. In an embodiment of the invention, the first temperature may be within a range of from about 800° C. to about 950° C. In certain embodiments of the invention, the first temperature is about 850° C. In yet other embodiments of the invention, the first temperature is about 900° C. In an embodiment of the invention, the second temperature may be within a range of from about 1000° C. to about 1100° C. In certain embodiments of the invention, the second temperature may be about 10⁻⁵⁰° C.

In conventional annealing processes, the inert gas is selected such that the gas transports the required heat energy to the semiconductor during the annealing process but does not interact with the polysilicon layer. In the present invention, the polysilicon layer is substantially covered by a silicon nitride and/or silicon oxynitride film, thus the possibility of interaction of the inert gas with the polysilicon layer is somewhat alleviated. According to certain embodiments of the invention, the inert gas is selected such that it preferentially transports the required heat energy to the semiconductor during the annealing process but does not substantially interact with the applied film or applied film layer. In certain embodiments of the invention, the inert gas may be any one of or any combination of nitrogen, oxygen, argon, and helium. In certain embodiments of the invention, the inert gas is any one of or a combination of oxygen and nitrogen. In an embodiment of the invention, the flow rate of the inert gas may be any value in a range of from about 100 to about 300 standard cubic centimeters per minute (sccm).

In an embodiment of the invention, the amount of annealing time may be within a range of from about 60 minutes to about 90 minutes. In certain embodiments of the invention, the annealing time will depend upon the annealing temperature. In certain embodiments of the invention, as further described herein, the annealing time at a first annealing temperature that is lower than a second annealing temperature may be within a range of from about 30 minutes to about 60 minutes, from about 35 minutes to about 55 minutes, from about 30 minutes to about 50 minutes, and from about 40 minutes to about 60 minutes. In certain embodiments of the invention, as further described herein, the annealing time at a second annealing temperature that is higher than a first annealing temperature may be within a range of from about 15 minutes to about 30 minutes, from about 20 minutes to about 30 minutes, from about 20 minutes to about 40 minutes, and from about 30 minutes to about 45 minutes.

In certain embodiments of the invention, the extent of annealing and application of the film or film layer may be balanced against the extent of implantation energy used to deposit the dopant in the polysilicon layer.

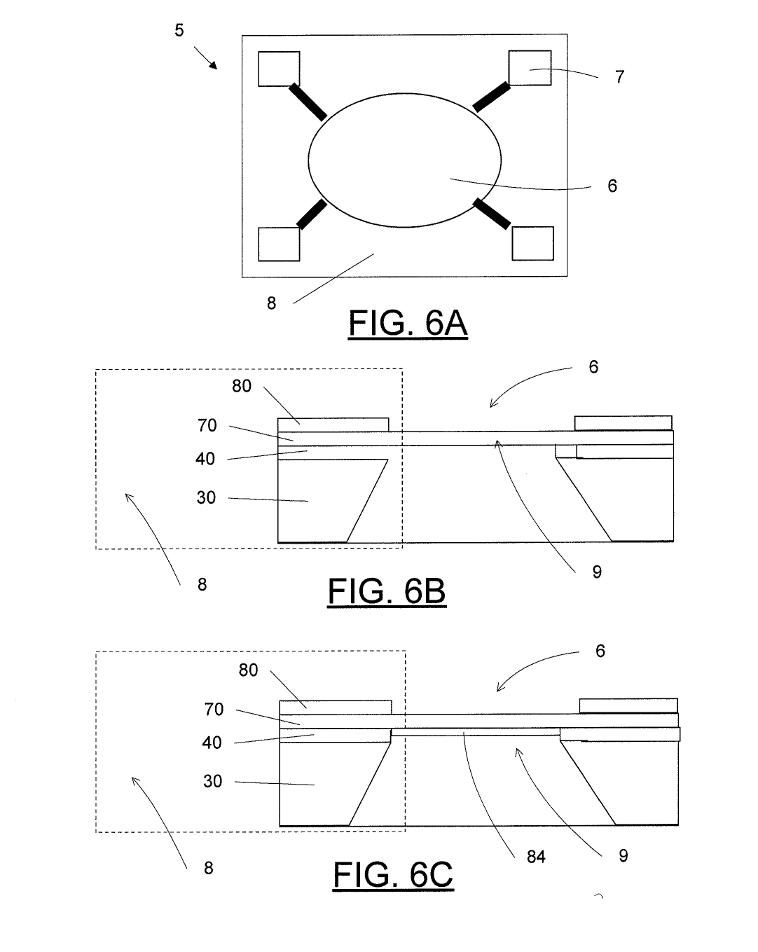

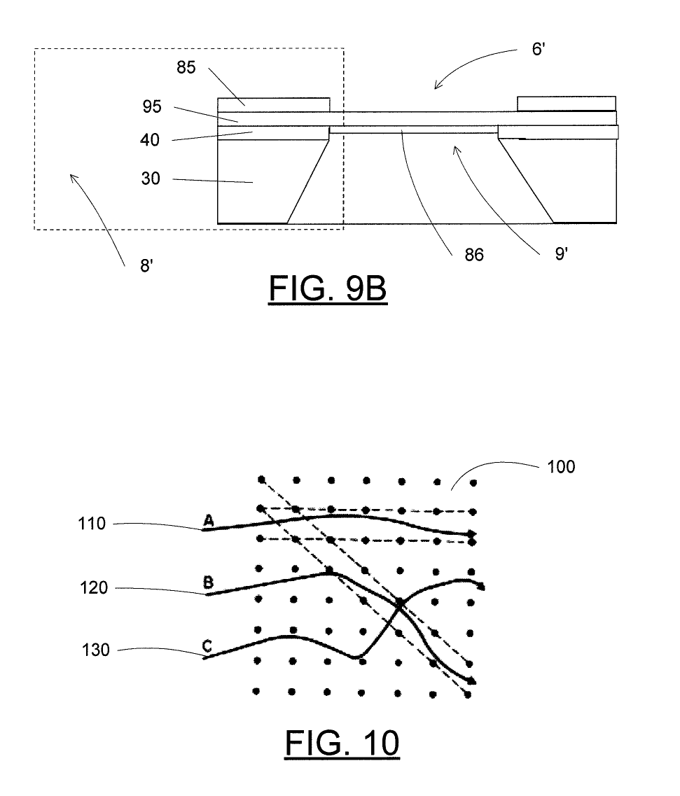

Following annealing, the film or the film layer is removed from the semiconductor. In an embodiment of the invention, the film or film layer is removed by a wetting process. In certain embodiments of the invention, the film or the film layer comprising silicon nitride may be removed by using a hot phosphoric acid (H₃PO₄). In certain embodiments of the invention, the film or the film layer comprising silicon oxynitride may be removed by a hydrofluoric (HF) acid based solution. FIGS. 6B, 6C and 9A, 9B illustrate cross sections of a semiconductor, according to certain embodiments of the invention, that have either been encapsulated by a film or by an applied film layer, respectively, after the removal of such film or film layer.

FIG. 6A is a sketch of a discrete semiconductor die, according to an embodiment of the invention. The discrete semiconductor die 5 having a main device area 6 or an active area, at least one bonding pad connect circuit 7, and a periphery area 8 at least in part configured to provide a support frame for the semiconductor die 5, according to certain embodiments of the invention. In certain embodiments of the invention, the periphery area 8 with the remaining encapsulated film is configured to support the semiconductor die, and the main active area that releases the membrane configured to respond to any environmental change.

In an embodiment of the invention, a residual film layer may continue to reside on a surface of the discrete semiconductor die once the film 80 has been removed. For example, FIG. 6B shows an illustrative exemplary embodiment where a residual film layer of the film 80 remains disposed substantially at the periphery of the semiconductor die as a supporting frame, the semiconductor device having a main device area 6, a periphery area 8, and a membrane 9. For example, according to an embodiment of the invention, the residual film layer may comprise any one or both of a silicon nitride or a silicon oxynitride.

FIG. 6C illustrates a cross section of a semiconductor after removal of the encapsulated film according to another embodiment of the invention. The illustrative embodiment of FIG. 6C shows a remaining dielectric film 84 that is configured to provide a desired stress according to the teachings further provided herein.

According to certain embodiments of the invention, the film layer 85 of FIGS. 7 and 8 may be disposed such that a residual film layer may continue to be disposed at periphery of a semiconductor die as a supporting frame once a portion of the film layer 85 has been removed. For example, according to an embodiment of the invention, the residual film layer 85 may comprise any one or both of a silicon nitride or a silicon oxynitride.

FIG. 9A shows an illustrative exemplary embodiment where a residual film layer of the film layer 85 remains disposed substantially at the periphery of the semiconductor die as a supporting frame, the semiconductor device having a main device area 6′, a periphery area 8′, and a membrane 9′. For example, according to an embodiment of the invention, the residual film layer may comprise any one or both of a silicon nitride or a silicon oxynitride.

FIG. 9B illustrates a cross section of a semiconductor after removal of the encapsulated film according to another embodiment of the invention. The illustrative embodiment of FIG. 9B shows a remaining dielectric film 86 that is configured to provide a desired stress according to the teachings further provided herein.

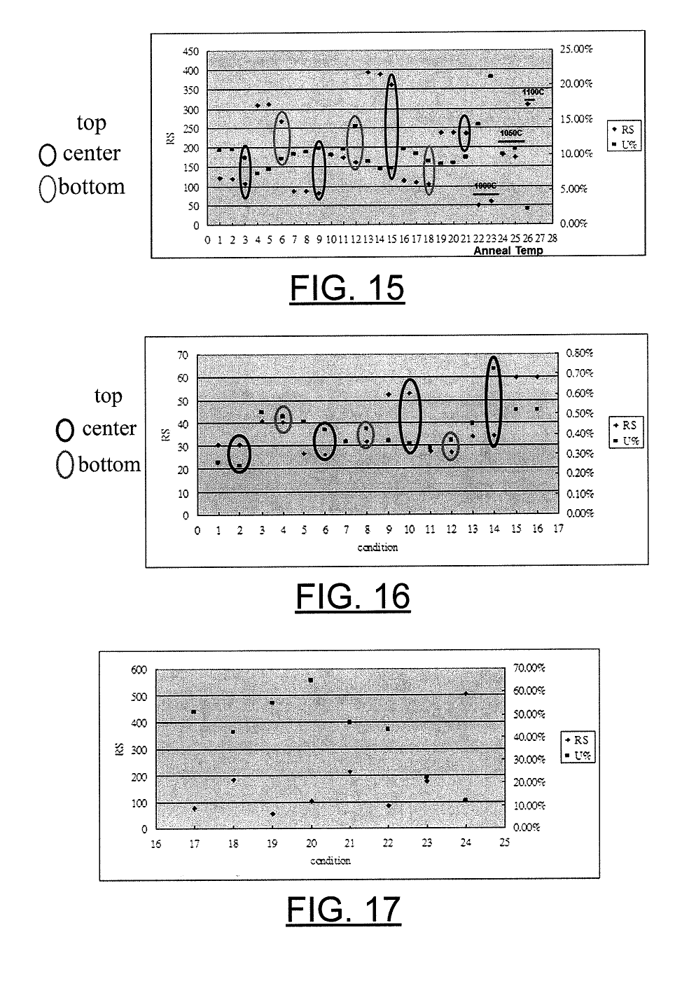

The experiments of Table 5 are reflected in FIG. 15, which is a graphical representation of polycrystalline silicone resistivity versus implantation energy and dosage, where the semiconductor has not be encapsulated using a film or a film layer disposed substantially across the polysilicon layer. The data shows that the resistivity of the polysilicon may vary between about 8 and 15%. Additionally, this data shows the resistivity of the polysilicon layer increases as the annealing temperature increases.

TABLE 5

| Data Points (x-axis) | Anneal Temperature, ° C. | Anneal Time, hr |
|---|---|---|
| 1-3 | 1050 | 1 |
| 4-6 | 1050 | 1 |
| 7-9 | 1050 | 1 |
| 10-12 | 1050 | 1 |
| 13-15 | 1050 | 1 |
| 16-18 | 1050 | 1 |
| 19-21 | 1050 | 1 |
| 22-23 | 1000 | 1 |
| 24-25 | 1050 | 1 |
| 26 | 1100 | 1 |

FIG. 16 is a graphical representation of polysilicon resistivity of a semiconductor that has been encapsulated with a film, according to certain embodiments of the invention, prior to being subjected to annealing at a temperature of 1050° C. for about 1 hour. As this data shows in comparison to FIG. 15, there is a marked reduction in resistivity as a result of employing the methods of the invention. Additionally, there is a substantial reduction in the variation of the resistivity of the various experiments.

For purposes of comparison, FIG. 17 is a graphical representation of polysilicon resistivity of a semiconductor that has not been encapsulated with a film that has been subjected to annealing at a temperature of 1050° C. for about 1 hour. As the data in this figure shows, there is a large increase in resistivity of these devices and a substantial variation in resistivity between the various devices.

The semiconductor of the invention may be applied to any number of semiconductor based devices, in particular, those devices where a desired tensile stress is important and, perhaps, a reduced and/or consistent resistivity has significance. According to an embodiment, the semiconductor of the invention is used in a micromechanical sensor and/or actuator. In another embodiment, the semiconductor of the invention may be used in complementary metal oxide semiconductor (“CMOS”), in particular, by way of example without intending to be limiting, the gate structure, interconnect, and/or resistor of the CMOS.

An aspect of the invention provides a method of fabricating a semiconductor. While the order of the steps of the method for fabricating a semiconductor may be variable, generally, the steps include providing a substrate, forming a dielectric layer on the substrate, depositing a polysilicon layer on the dielectric layer, applying a film to the substrate, annealing the semiconductor, and removing the film from the substrate. According to an embodiment of the invention the polysilicon layer is deposited onto the dielectric layer at a deposition temperature, wherein the deposition temperature is within a range of from about 580° C. to about 595° C. In certain embodiments of the invention, the film may encapsulate the semiconductor, while in certain other embodiments of the invention, the film may be substantially disposed across the surface of the polysilicon layer.

The step of annealing the semiconductor comprises increasing a temperature of the semiconductor to a first temperature and holding the semiconductor at about the first temperature for a first amount of time. In an embodiment of the invention, the first temperature is within a range of from about 800° C. to about 950° C. The step of annealing the semiconductor may additional comprise increasing the temperature of the semiconductor to a second temperature and holding the semiconductor at about the second temperature for a second amount of time. In certain embodiments of the invention, the second temperature is within a range of from about 1000° C. to about 1100° C.

According to certain embodiments of the invention, the first amount of time is about the same as the second amount of time, while in other embodiments of the invention, the first amount of time is greater than the second amount of time. In certain embodiments of the invention, the first amount of time is within a range of from about 30 minutes to about 60 minutes, while the second amount of time is within a range of from about 10 minutes to about 45 minutes.

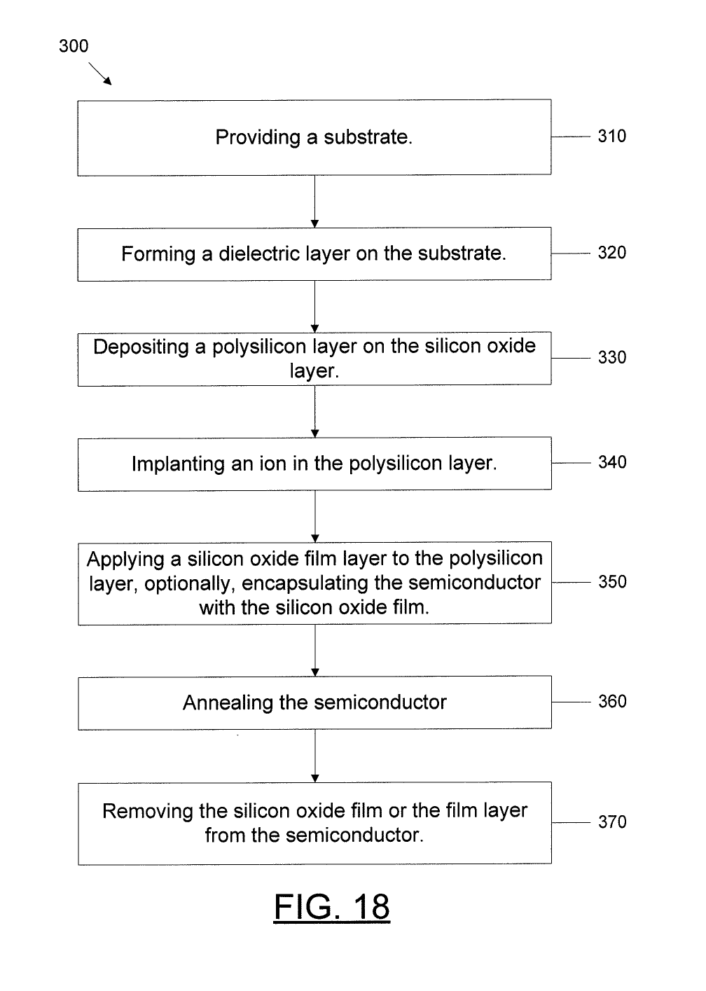

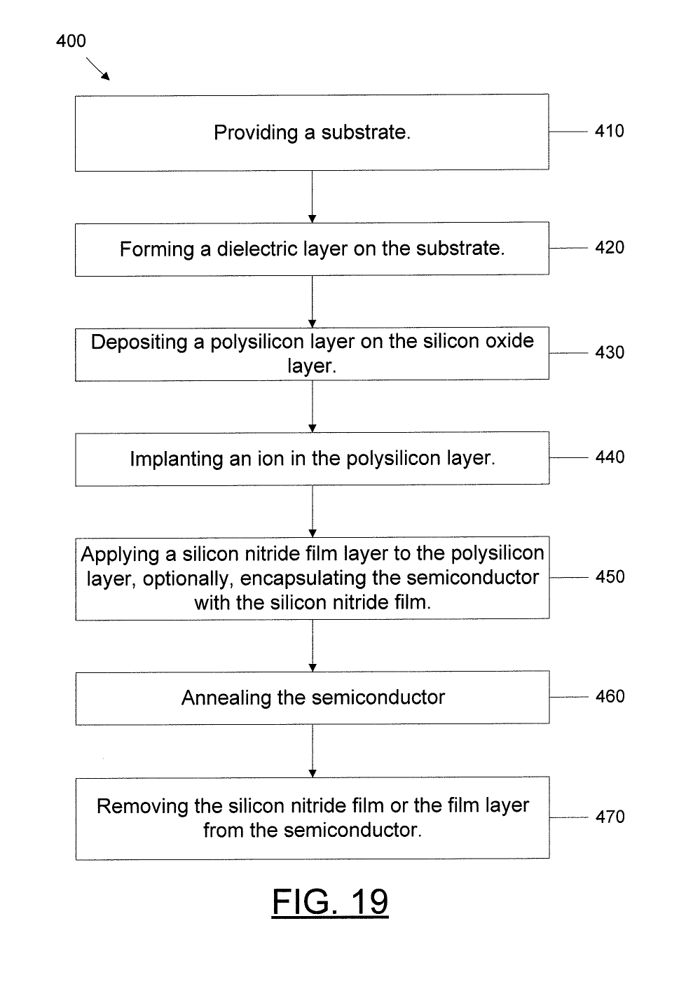

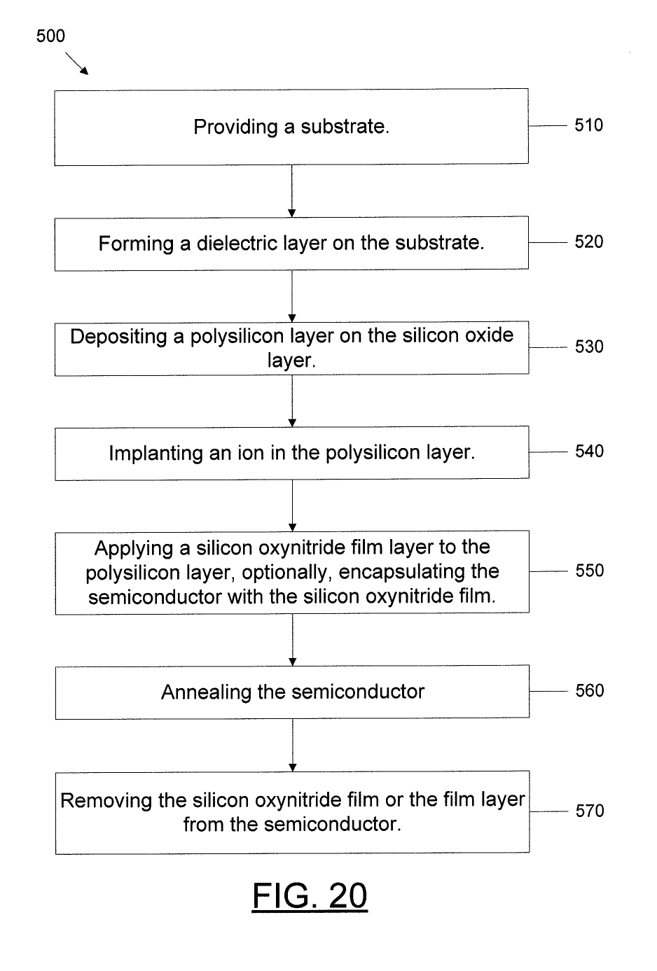

FIGS. 18-20 are flowcharts illustrating various embodiments of a method for fabricating a semiconductor according to the invention. FIG. 18 is representative of the embodiment whereby a film layer comprising silicon oxide is applied to the semiconductor. Optionally, a silicon oxide based film may encapsulate the semiconductor. FIG. 19 is representative of the embodiment whereby a film layer comprising silicon nitride is applied to the semiconductor. Optionally, a silicon nitride based film may encapsulate the semiconductor. FIG. 20 is representative of the embodiment whereby a film layer comprising silicon oxynitride is applied to the semiconductor. Optionally, a silicon oxynitride based film may encapsulate the semiconductor.

An aspect of the invention provides a semiconductor fabricated using the processes or methods for fabricating a semiconductor of the invention. In certain other embodiments of the invention, a semiconductor device may be fabricated using any methods as described herein.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A method of fabricating a semiconductor comprising:
forming a dielectric layer on a substrate;
depositing a polysilicon layer on the dielectric layer at a deposition temperature;
applying a film to the semiconductor; and
annealing the semiconductor.

2. The method of claim 1, additionally comprising removing the film from the semiconductor.

3. The method of claim 2, wherein a residual film continues to be disposed along at least a periphery of a semiconductor die.

4. The method of claim 3, wherein the residual film comprises at least one of a silicon nitride, a silicon oxynitride, and any combination thereof.

5. The method of claim 1, wherein the dielectric layer comprises at least one of a silicon oxide and a silicon oxynitride.

6. The method of claim 1, wherein the deposition temperature is from about 580° C. to about 595° C.

7. The method of claim 6, wherein the deposition temperature is from about 580° C. to about 585° C.

8. The method of claim 1, wherein the film substantially encapsulates the semiconductor.

9. The method of claim 1, wherein the film is substantially disposed across the polysilicon layer.

10. The method of claim 1, wherein the film comprises at least one of a silicon oxide, a silicon nitride, and a silicon oxynitride.

11. The method of claim 1, wherein annealing the semiconductor comprises increasing a temperature of the semiconductor to a first temperature and holding the semiconductor at the first temperature for a first amount of time.

12. The method of claim 11, wherein annealing the semiconductor comprises increasing the temperature of the semiconductor to a second temperature and holding the semiconductor at the second temperature for a second amount of time.

13. The method of claim 12, wherein the first temperature is from about 800° C. to about 950° C. and the second temperature is from about 1000° C. to about 1100° C.

14. The method of claim 13, wherein the first amount of time is greater than the second amount of time.

15. The method of claim 2, wherein the film comprises a silicon nitride and the film is removed using a wet process comprising a hot phosphoric acid.

16. The method of claim 2, wherein the film comprises a silicon oxynitride and the film is removed using a wet process comprising a hydrofluoric acid based solution.

17. A semiconductor comprising:
a substrate;
a dielectric layer disposed adjacent to the substrate; and
a polysilicon layer disposed adjacent to the dielectric layer, the polysilicon layer having a stress of from about 10 MPa to about 40 MPa.

18. The semiconductor of claim 17, wherein the dielectric layer comprises a silicon oxide and a stress of the dielectric layer is from about −330 MPa to about −270 MPa.

19. The semiconductor of claim 17, wherein the dielectric layer comprises at least one of:
a silicon oxide layer having a stress of about −145 MPa to about −105 MPa, and
a silicon oxynitride layer having a stress of about 10 MPa to about 30 MPa.

20. The semiconductor of claim 17 additionally comprising a film, wherein the film is at least one of applied to a surface of the polysilicon layer and substantially encapsulates the semiconductor.

21. The semiconductor of claim 20, wherein the film comprises any one of a silicon nitride or a silicon oxynitride.

22. A semiconductor comprising:
a substrate;
a dielectric layer disposed adjacent to the substrate;
a polysilicon layer disposed adjacent to the dielectric layer, wherein the polysilicon layer has a uniform dopant profile through the grain and across the grain; and
a residual film layer disposed along a periphery of a semiconductor die as a supporting frame.

23. (canceled)

24. The semiconductor of claim 23, wherein the residual film layer comprises at least one of a silicon nitride, a silicon oxynitride, and any combination thereof.
